(19) United States
(12) Patent Application Publication
(10) Pub. No.: US 2014/0278257 A1
(43) Pub. Date: Sep. 18, 2014

(54) PROBE COMMUNICATIONS MODULE AND A COMPUTING DEVICE

(71) Applicant: DEFELSKO CORPORATION, Ogdensburg, NY (US)

(72) Inventor: Leon VANDERVALK, Brockville (CA)

(73) Assignee: DEFELSKO CORPORATION, Ogdensburg, NY (US)

(21) Appl. No.: 14/203,718

(22) Filed: Mar. 11, 2014

Related U.S. Application Data
(60) Provisional application No. 61/798,157, filed on Mar. 15, 2013.

(51) Int. Cl. G01R 1/067

(52) U.S. Cl. CPC G01R 1/067
USPC 702/189

(57) ABSTRACT

A probe communications module interfaces with an interchangeable digital probe to transmit measurements to a computing device so that the operator may conveniently gather measurements using the interchangeable digital probe and, using the computing device, display, annotate, compare, and analyze the measurements.

### CROSS-REFERENCE TO RELATED APPLICATIONS

This application claims the priority benefit of U.S. Provisional Application No. 61/798,157 filed on Mar. 15, 2013, and entitled PROBE COMMUNICATIONS MODULE AND A COMPUTING DEVICE, the entire content of which is incorporated herein by reference.

### TECHNICAL FIELD

The present invention relates to an interface for probes, and more particularly, a probe communications module for linking interchangeable digital probes to a computing device such as a computer or a portable computing device like a smartphone.

### BACKGROUND

Conventional gages include a body that can connect to and utilize a variety of probes. Probes produce an electronic signal that is responsive to measured physical quantities. A probe may use, for example, the magnetic principle to measure the thickness of non-magnetic coatings on ferrous metals. Another example is a probe that uses the eddy current principle to measure the thickness of non-conductive coatings on non-ferrous metals. A probe may also rely on both of these principles so that the thickness of coatings on ferrous and non-ferrous metals may be measured with a single device. Other probes are configured to measure the peak to valley surface profiles, environmental conditions like relative humidity, air temperature, surface temperature, dew point temperature, adhesion of coatings to rigid substrates, and other physical attributes. Some of these known probes are described in commonly owned U.S. Pat. No. RE41,342 entitled COATING THICKNESS GAUGE which is incorporated herein by reference.

In conventional gages, the body receives information from the probe that represents a parameter that is being measured. Typically, this information is processed by the body and converted to a calibrated measurement that is displayed to an operator and or stored for future analysis. The stored measurement may then downloaded and analyzed using known analytical methods in another device, typically a personal computer located in an office or other fixed location.

When using known probes, operators may at times require the ability to contemporaneously annotate the information being collected by the probe. Traditional techniques have included using electronic and paper notebooks, standalone cameras, and report templates. More recently, applications have been developed that allow operators to annotate measurements without relying on a personal computer located in a fixed location. The probe measurements and annotations entered by such applications must, however, be synchronized by the operator so that a report with both the probe measurements and the annotations may be generated.

Improvements in mobile computing capabilities including increased processing speed and memory capacity now provide the opportunity to simplify the process of measuring and analyzing the measurements gathered by probes. Portable computing devices are now capable of performing a variety of tasks including voice input, determining GPS coordinates, and taking of pictures via on board cameras, and also include sufficient processing power to perform sophisticated analytics on larger data sets. Portable computing devices also now include user interfaces, such as touch screen interfaces, which are intuitive to the typical user and which are also easily adapted by a program executing on the portable computing device. This allows a single portable computing device to execute multiple programs, where each program can customize the user interface so that the user can more easily interact with the program. Many portable computing platforms now also include industry standard communications hardware, including Wi-Fi, Bluetooth, and ZigBee, among others.

Known probes, including known digital probes, are not compatible with portable computing platforms. The present application allows existing digital probes to interact with portable computing platforms and helps improve the usability of known probes while also addressing the above described problems.

### SUMMARY

It is desirable to allow for digital probes to communicate with portable computing devices that incorporate a highly configurable user interface and sufficient processing power to manipulate a data set. It is further desirable to allow for existing digital probes already owned by an operator for use with conventional gages to be used with portable computing devices. It is still further desirable to allow for existing digital probes to communicate in an industry standard manner with portable computing devices while still preserving the ability for existing digital probes to be used with conventional gages.

It is also desirable to allow for operators of the digital probes and the portable computing devices to contemporaneously annotate measurements using the easily adapted user interfaces available on typical portable computing devices. It is further desirable to allow for the operator to synchronize these annotations with the probe measurements so that a report may be generated, even if the operator is not at a fixed location.

### BRIEF DESCRIPTION OF THE DRAWING FIGURES

The probe communications module will now be described by way of exemplary embodiments to which it is not limited by reference to the accompanying drawings, in which:

FIG. 1 depicts several examples of interchangeable digital probes that may be attached to the probe communications module.

FIG. 2 illustrates a probe communications module secured and connected to an interchangeable probe.

FIG. 3 depicts an exploded view of the probe communications module.

FIG. 4 illustrates one embodiment of a system for using interchangeable probes with the probe communications module.

FIG. 5 illustrates another embodiment of a system for using interchangeable probes.

FIG. 6 illustrates the embodiment of the computing device from FIG. 4 with another embodiment of a probe that includes wireless capabilities.

FIG. 7 illustrates a flow chart that describes the typical operation of the probe communications module with the interchangeable probe and the portable computing device.

### DETAILED DESCRIPTION OF THE INVENTION

The present disclosure describes how existing digital probes may be used with portable computing devices so that the highly configurable user interface available on portable computing devices may provide operators additional functionality that helps improve operator efficiency while also minimizing the amount of additional equipment required.

### Interchangeable Digital Probes

Interchangeable digital probes have been used in industry for many years and have been described in documents including U.S. Pat. No. 5,293,132, entitled COATING THICKNESS MEASUREMENT GAUGE, which is hereby incorporated herein by reference. These probes may contain transducers for measuring a variety of physical parameters such as magnetic field strength. Other probes may include piezoelectrical components for converting vibrations into a voltage, coils of wire used to measure the eddy currents on a conductive surface, and other sensing systems. The interchangeable digital probes measure the physical parameters, convert these readings into measurable quantities such as a voltage, and convert these measurable quantities into a digital format. The interchangeable digital probes may also include non-volatile memory for storing information. For example, calibration information specific to the interchangeable digital probe may be stored in the non-volatile memory so that the gage body can convert the measurements into a calibrated measurement.

Interchangeable probes typically interface with a gage body using a proprietary interface to communicate with the gage body. The proprietary interface includes a physical connection that results in both mechanical and electrical contact. The digitally formatted electrical signals are transmitted using this proprietary interface to the gage body. Additionally, other electrical connections including a power connection for the interchangeable probe may be established using the proprietary interface. In one example, the electrical connections include a bidirectional serial interface. Other electrical connections suitable for this purpose are known in the art and are not specifically enumerated here.

FIG. 1 depicts several examples of interchangeable digital probes 10. The top portion 12 of the interchangeable probe 10 includes physical structures for securing to a gage body and electrical connections for connecting to the gage body. The electrical connection may comprise a means to power the probe 10 and a means to transfer the digital measurements taken by the probe 10 to the gage body. In one example, the interchangeable digital probes 10 may include a bidirectional serial interface for transferring the digital measurements from the probe 10 to the gage body.

### Probe Communications Module

A probe communications module 20 is configured to be physically secured and electrically connected to the interchangeable digital probes 10. The probe communications module 20 may be secured to any portion of the interchangeable probe so long as the probe communications module 20 is physically secured and electrically connected to the interchangeable probe 10. In one example embodiment shown in FIG. 2, the probe communications module 20 may interface with the interchangeable probe 10 using the proprietary interface that would connect the interchangeable probe 10 to a gage body. In this example embodiment, an operator's existing collection of interchangeable digital probes 10 may be used with a conventional gage body, and these same probes may also be used with the probe communications module 20.

FIG. 3 provides an exploded view of some of the components that comprise the probe communications module 20. The probe communications module 20 includes a housing 21 that is durable and waterproof so that when the interchangeable probe 10 and probe communications module 20 are physically secured and electrically connected to each other, the combined device may be used in a variety of conditions including high and low temperatures, in the presence of solvents, acids, oils, liquids, and other difficult conditions where the measurement of physical properties is desirable. This is because when the probe communications module 20 is physically secured to the interchangeable probe 10, an environmentally resilient seal is established between the probe communications module 20 and the interchangeable probe 10 that prevents the entry of environmental contaminants. The environmentally resilient seal may be established using gaskets, rubber seals, and other components known to those of skill in the art and are not specifically enumerated here. The housing 21 of the probe communications module 20 may include the necessary environmental seals to prevent the entry of environmental contaminants. In an alternate embodiment, the interchangeable probe 10 may include environmental seals. In a further embodiment, both the housing 21 of the probe communications module 20 and the interchangeable probe 10 may include environmental seals that cooperate to prevent the entry of environmental contaminants.

The housing 21 of the probe communications module 20 may be shaped in a manner so that the combined interchangeable probe 10 and the probe communications module 20 are ergonomic and easy for a user to grasp and to manipulate, even in difficult conditions. The housing 21 of the probe communications module 20 may include physical features that help secure the probe communications module 20 to the interchangeable probe 10. Alternatively, the interchangeable probe 10 may include physical features to help secure the probe communications module 20 to the interchangeable probe 10. In a further embodiment, both the housing 21 of the probe communications module 20 and the interchangeable probe 10 may include physical features to help secure the probe communications module 20 to the interchangeable probe 10. The physical features may include prongs, tabs, or other features known in the art for securing components. In the example embodiment shown in FIG. 3, a remote lock plate 22 includes physical features that allow the probe communications module 20 to be secured to the interchangeable probe 10. These physical features may be the same physical features that comprise the proprietary interface that secures the interchangeable digital probe 10 to the gage body. This provides the advantage of allowing the operator to use an existing collection of interchangeable digital probes with either a conventional gage body or with the probe communications module, thereby reducing operator expense.

When the probe communications module 20 is physically secured to the interchangeable probe 10, as shown in FIG. 2, the probe communications module 20 is also electrically connected to the interchangeable probe 10. The electrical connection between the probe communications module 20 and the interchangeable probe 10 allows for the electrical signals produced by the interchangeable probe 10 to be transferred to a data interface in the probe communications module 20. The electrical connection between the probe communications module 20 and the interchangeable probe 10 may also allow for a power source in the probe communications module 20 to power the interchangeable probe 10. Other electrical connections are known in the art and are not specifically enumerated here.

In an alternate embodiment of the probe communications module 20, the probe communications module 20 is an integral part of the interchangeable probe 10. That is, the probe communications module 20 is physically secured and electrically connected to the interchangeable probe 10 in a permanent fashion.

The housing 21 of the probe communications module 20 encloses a PCB 23 with a data processor, a bidirectional data interface for communicating with the interchangeable probe 10, and a communications interface for bidirectional communication with a computing device. The housing 21 of the probe communications module 20 may also include memory usable by the data processor. For example, the memory may be used to store calibration information that is received from a computing device by way of the communications interface. In another example, the memory may be used to store characterization information from the probe 10. An example of such characterization information may include coefficients for an equation that characterizes the probe 10. In a still further example, the memory may be used to store probe identifying information like a serial number or other identifier. This identifying information may be used to associate specific information, which is also stored in the memory of the probe communications module 20, with a particular probe. For example, a probe identifier may associate calibration information, stored in the probe communications module 20 memory, with the probe 10 currently connected with the probe communications module 20. Other types of information may also be stored in the memory used by the data processor and are not specifically enumerated here. The housing 21 of the probe communications module 20 may also enclose a power source to power the components of the probe communications module 20.

The housing 21 of the probe communications module 20 may include a button 24 or other triggering component to activate both the probe communications module 20 and the interchangeable probe 10. This allows the operator to selectively activate the probe communications module 20 and the interchangeable probe 10 to conserve power. The housing 21 of the probe communications module 20 also may include visual indicators, such as LEDs, to indicate the status of the probe communications module 20.

The probe communications module 20 includes a data processor that translates the digital signals representing the measurements into a format suitable for transmitting to a computing device. The data processor may use the memory in the probe communications module 20 to store the data prior to transmission to the computing device. The data processor may also use characterization information that is stored in the interchangeable digital probe 10 so that a calibrated measurement may be obtained from the probe 10. The data processor may also handle other tasks such as determining when the interchangeable probe 10 is positioned near a surface, like a metal surface, and initiating the collection of measurement information at predefined intervals. The data processor may also switch the mode of measurement of the interchangeable probe 10 when the interchangeable probe 10 can use multiple forms of measurement. In one example embodiment, the interchangeable probe 10 may first use a magnetic principle to attempt a measurement. If a usable reading cannot be obtained, the data processor may instruct the interchangeable probe 10 to use an eddy current principle to attempt a measurement.

The data interface receives the electrical signals from the interchangeable probe 10 and performs any needed preprocessing before transferring information to the data processor. In one example embodiment, the data interface uses the same interface that a conventional gage body would use to receive the electrical signals from the interchangeable probe 10.

The communications interface establishes a bidirectional communications link between the probe communications module 20 and a computing device. The communications interface may use standard communications techniques to connect to the computing device. For example, the communications interface may transmit the data to the computing device and receive information from the computing device using a wireless data transmission method like Bluetooth, Bluetooth Low Energy, Zigbee, GPRS, Wi-Fi, or another standard wireless data transmission method. In an alternate embodiment, the communications interface may also transmit the data to the computing device and receive information from the computing device using a proprietary wireless data transmission method. In a further embodiment, the communications interface may use a wired or otherwise physical interface to transmit the data to the computing device and receive information from the computing device using a data transmission method. For example, the communications interface may use a standard port, such as a Universal Serial Bus (USB) port to transfer data to the computing device and receive information from the computing device. In an alternate embodiment, the communications interface may also use a standard port in a different manner to transmit the data to the computing device and receive information from the computing device using a data transmission method. For example, the communications interface may convert the data into an audio signal so that the data may be transmitted to the computing device and information may be received from the computing device using a standard audio connection. Other methods of transmitting the data from the probe communications module 20 to the computing device and transmitting information using a data transmission method are known to those of skill in the art and are not specifically enumerated here.

The communications interface may transmit any data from the interchangeable probe 10. The communications interface may also receive commands and other information from the computing device. For example, the computing device may instruct the probe communications module 20 data processor to use different calibration information based on user input. Other commands may be transmitted to the computing device through the communications interface and are not specifically enumerated here.

In addition to the tasks above, the data processor of the probe communications module 20 also configures the information for use with the communications interface. For example, when the probe communications module 20 uses a communications interface that transmits data using Bluetooth Low Energy, the data processor may configure a profile that updates a measurement characteristic whenever a new measurement is acquired by the probe communications module. The data processor may also use information stored in the probe communications module 20 memory to adjust the data being transmitted to the computing device. For example, the data processor may use calibration information, stored in the probe communications module 20 memory, to adjust the data being transmitted to the computing device so that the data provided to the portable computing device is accurate. The data processor may create the profile based on the generic attribute profile (GATT) so that data may be transmitted to the computing device over a low energy link. In this example, the data processor uses server GATT commands and updates to a characteristic in the profile to signal to the computing device that the probe 10 has taken a measurement.

After the data processor has signaled to the computing device that the probe has taken a measurement, the communications interface of the probe communications module 20 transmits the data generated by the data processor based on the electrical signals generated by the interchangeable probe 10 to the computing device, to be described later.

The operation of the probe communications module 20 in conjunction with the interchangeable digital probe 10 will now be described. The flowchart in FIG. 7 illustrates the operation of the probe communications module 20. The operator first actuates button 24 to activate the probe communications module 20 and initialize the interchangeable probe 10. The operator's actuation of button 24 also activates the communications interface of the probe communications module 20 and sets up a link to the computing device. After these tasks are completed, the interchangeable probe 10 is ready to collect measurements. The probe communications module 20 receives measurements from the interchangeable probe 10 via the data interface in the form of digital signals. The data processor processes these digital signals and makes the necessary conversions for transmission to the computing device. If necessary, the data processor may also use information contained in the interchangeable probe 10 so that a calibrated measurement may be obtained. For example, the data processor may use calibration adjustments to adjust the data so that a calibrated measurement is transmitted to the computing device. The data processor also executes any commands or updates necessary to notify the computing device that a measurement has been taken. For example, the data processor may use server GATT commands and update a characteristic in the profile to signal to the computing device that the probe 10 has taken a measurement. The communications interface then transfers the data to the computing device. After a series of measurements are taken, or after a period of time has elapsed where no measurements have been taken, the probe communications module 20 may enter a power-saving mode. When further readings are desired, the operator may press the button 24 and reinitialize the probe 10, the probe communications module 20, and reestablish the link to the computing device so that further measurements may be taken.

### Computing Device

The computing device includes a display, an input portion, a processor, memory, and a probe data interface. The computing device display may be a high resolution screen color display. The computing device input portion may include physical buttons or may be a touchscreen interface. In an alternate embodiment, the display and the touchscreen interface may be an integral component such as a touchscreen display. Additionally, the input portion of the computing device may include voice to text conversion, GPS coordinates, and or pictures acquired using a camera built into the computing device.

The computing device includes a processor for executing various programs stored in the computing device memory. The computing device memory stores programs for execution and data generated by the programs, among other items. The computing device also includes a data interface for receiving data from the probe communications module 20. The computing device probe data interface uses a data transmission method that corresponds to the data transmission method used by the communications interface of the probe communications module 20. The computing device may manage multiple probe communications modules 20 concurrently or individually. Preferred embodiments of the computing device may include personal computers, smartphones, or other devices. These embodiments all share a common feature of providing a user interface for the operator and providing additional processing and memory capability, in addition to the processing and memory capability of the probe communications module 20. One exemplary embodiment of a computing device 30 is shown in FIG. 4.

FIG. 4 illustrates the computing device 30 communicating with a probe communications module 20 that is attached to an interchangeable probe 10. The probe communications module 20 of this embodiment transmits data to the computing device 30 and receives information from the computing device 30 using the previously described wireless data transmission methods.

FIG. 5 depicts another embodiment where the interchangeable probe 10 directly connects with the computing device 30. In other words, the interchangeable probe 10 communicates directly with the computing device 30 by way of an electrical connection between the interchangeable probe 10 and the computing device 30. This particular embodiment does not require the use of the probe communications module 20 because a direct electrical connection is established to transfer information to the computing device 30. The direct electrical connection may be established by way of a standard USB port or by using a standard port in a different manner, as previously described.

FIG. 6 depicts a device 15 that integrates the probe and the probe communications module. In this embodiment, the device 15 includes the components necessary to process the electrical signals that are responsive to measured physical quantities into information that may be transmitted to the computing device 30, in addition to the components necessary to receive information from the computing device 30. In other words, device 15 includes all the necessary components to communicate with the computing device 30.

### Program Executed by the Computing Device

A program executed by the computing device 30 allows the computing device 30 to receive the data from the probe communications module 20 and also allows the computing device to transmit information to the probe communications module 20. The program may be installed onto the computing device 30 using known techniques. When executed, the program may cause the computing device 30 to transmit to the probe communications module 20 a command to initiate transfer of data stored in the probe communications module 20. In an alternate embodiment, the program may cause the probe communications module 20 to transfer data as the data is processed by the data processor of the probe so that a series of measurements from the interchangeable digital probe is received. In an example where the probe communication module 20 uses Bluetooth Low Energy, the program may instruct the computing device to activate a Bluetooth communications module so that when the probe communications module 20 data processor uses a server GATT command and updates a characteristic in the profile, the computing device can receive the updated measurement.

The program may also adjust measurements received from the interchangeable probe 10. For example, 1-point and 2-point adjustment may be employed to adjust the interchangeable probe 10 measurement The program may also store a particular calibration adjustment for an interchangeable probe 10 so that the interchangeable probe 10 may adjusted, disconnected from the computing device, and later reconnected to the computing device, without requiring another adjustment step. The program may identify the interchangeable probe 10 and the corresponding adjustment setting with or without user intervention. The program may adjust the measurement speed of the interchangeable probe 10 by adjusting the predetermined interval between measurements.

The program is also suitable for viewing and annotating the data collected by the interchangeable digital probe 10. For example, the program may generate charts, graphs, or other representations of the data so that the operator can quickly and easily ascertain the measured values. For example, the data may be displayed in a histogram, chart, or other graphical format. The program may also adjust the displayed resolution of the data, and may also cause the computing device to adjust the display so that the information may be more easily read in a variety of environments. For example, the backlight of the computing device may be adjusted to enhance readability, or the colors of the display may be inverted. The program may also allow for changing the units of the data being displayed. For example, the operator may instruct the program to use metric units. The program would then convert the measurements, if necessary, and then update the representation of the data to reflect the changed unit.

The program may cause the computing device to visibly and audibly alert the user when the measurements meet user-specified thresholds. The program may also cause the computing device to visibly and audibly alert the user when a specified number of measurements have been made. The program may further cause the computing device to visibly and audibly alert the user when other conditions occur.

The program may also include a statistical analysis section. The statistical analysis section displays a summary of the data received from the probe communications module 20. The summary may include the mean, standard deviation, number of measurements, and the maximum and the minimum measurement of the received data. Other known methods of characterizing data are known in the art and are not specifically enumerated here. The summary may also include the last reading received from the probe communications module 20.

The program may manipulate the data in numerous ways. The program may allow the operator to create a grouping, or batch, of data, and a sub-groupings, or sub-batches, of data. Batches and sub-batches allow for the operator to group the data being received from the probe communications module 20. For example, the operator may designate a batch for one component of the item being measured, and may designate a separate batch for a different component of the item being measured. The operator may label the batches and sub-batches with unique identifiers.

The program may also allow the operator to compare measurements, batches of measurements, and sub-batches of measurements with other measurements, batches of measurements, and sub-batches of measurements. The program may also compare measurements, batches of measurements, and sub-batches of measurements against a known value, like a value from a predefined standard. For example, the program may compare the batches and sub-batches of data with a performance standard for protective coatings. The program may also allow the operator to define a particular value or set of values and compare the measurements, batches of measurements, and sub-batches of measurements to the user-defined value or set of values. The program may also allow the operator to annotate the measurements, and the batches and sub-batches of measurements. The operator may enter these annotations using the input portions of the computing device. These annotations may then be saved with the measurements, the batches of measurements, and the sub-batches of measurements.

The program may also transfer stored data to external data storage. The external storage may be physically attached to the computing device 30 or may be remotely accessible over a network. One example of remotely accessible storage is an Internet-based data storage system. The program may cause the computing device to connect to the Internet-based data storage system and transfer the stored data, including any annotations entered by the operator, to the Internet-based data storage system using known data transfer techniques. The program may also transfer stored data to another computing device using known data transfer techniques. The program may also export the stored data into a common data format for further manipulation by other programs and computing devices. The program may transfer the stored data to any of these devices or systems at predefined intervals or based on predetermined events. For example, the operator may instruct the program to transfer stored data after a predetermined number of measurements have been taken. The program may also allow an operator to manually initiate the transfer of information to external storage.

It will be understood that the foregoing description is of the preferred embodiments, and is, therefore, merely representative of the article. It can be appreciated that many variations and modifications of the different embodiments in light of the above teachings will be readily apparent to those skilled in the art. Accordingly, the exemplary embodiments, as well as alternative embodiments, may be made without departing from the spirit and scope of the articles and methods as set forth in the attached claims.

What is claimed is:

1. A probe communications module for connecting to an interchangeable digital probe, the probe communications module comprising:
an electrical interface for transmitting and receiving digital signals from the interchangeable digital probe;
a data processor for processing the digital signals from the interchangeable digital probe;
a communications interface for transmitting measurements processed by the data processor to a computing device, and for receiving information from the computing device; and
wherein the data processor notifies the computing device that a measurement has been taken by the interchangeable probe.

2. The probe communications module of claim 1,
wherein the data processor retrieves calibration information from the interchangeable digital probe and calibrates the digital signals from the interchangeable digital probe before transmitting the measurements to a computing device.

3. The probe communications module of claim 1,
wherein the communications interface receives commands for the data processor from the computing device.

4. The probe communications module of claim 1,
wherein the data processor instructs the interchangeable digital probe to take measurements using a first measurement technique.

5. The probe communications module of claim 4,
wherein the data processor instructs the interchangeable digital probe to take measurements using a second measurement technique.

6. A system for using interchangeable digital probes, the system comprising:
a probe communications module for connecting the interchangeable digital probe to a computing device, the probe communications module comprising:
an electrical interface for transmitting and receiving digital signals from the interchangeable digital probe;
a data processor for processing the digital signals from the interchangeable digital probe;
a communications interface for transmitting measurements processed by the data processor to a computing device, and for receiving information from the computing device; and
wherein the data processor signals to the computing device that a measurement has been taken by the interchangeable probe; and
a computing device comprising:
a processor,
an input portion for receiving operator input; and
a communications module for receiving the measurements from the probe communications module communications interface.

7. The system of claim 6,
wherein the computing device communications module receives notifications from the probe communication module that measurements have been taken.

8. The system of claim 6,
wherein the computing device further comprises an input portion for annotating the measurements received from the probe communications module, the annotations being stored in conjunction with the measurements in the computing device.

9. The system of claim 6,
wherein the computing device further comprises a transfer interface for transferring data to a storage device, wherein the data includes the measurements.

10. The system of claim 6,
wherein the computing device input portion is configured to receive operator commands for transmission to the probe communications module communications interface.

11. A method for connecting an interchangeable digital probe to a computing device with a probe communications module, the probe communications module including an electrical interface, a data processor, and a communications interface, the method comprising:
transmitting and receiving digital signals, using the electrical interface, from the interchangeable digital probe;
processing, using the data processor, the digital signals from the interchangeable digital probe, the processed digital signals being probe measurements;
notifying, using the communications interface, the computing device that the probe measurement has been taken; and
transmitting, using the communications interface, the probe measurements to the computing device.
